(19) United States
(12) Patent Application Publication
(10) Pub. No.: US 2015/0115442 A1
(43) Pub. Date: Apr. 30, 2015

(54) Redistribution layer and method of forming a redistribution layer

(71) Applicant: Infineon Technologies AG, Neubiberg (DE)

(72) Inventors: Georg MEYER-BERG, Munich (DE); Reinhard Pufall, Munich (DE)

(73) Assignee: Infineon Technologies AG, Neubiberg (DE)

(21) Appl. No.: 14/068,170

(22) Filed: Oct. 31, 2013

(51) Int. Cl. H01L 23/00

(52) U.S. Cl. CPC H01L 24/06; H01L 24/14; H01L 24/03; H01L 24/81; H01L 2224/02373; H01L 2224/02317
USPC 257/738; 257/762; 257/761; 438/618; 438/125

(57) ABSTRACT

A redistribution layer for a chip is provided, wherein the redistribution layer comprises at least one electrical conductor path connecting two connection points with each other, wherein the at least one electrical conductor path is arranged on a planar supporting layer and wherein the electrical conductor path comprises copper and at least one other further electrical conductive material in an amount of more than 0.04 mass percent.

### BACKGROUND

1. Field

The present invention relates to a redistribution layer. Moreover, the present invention relates to a method of forming a redistribution layer.

2. Description of the Related Art

In the art so-called ball grid arrays (BGA) are used for a plurality of applications in the field of packaged semiconductor chips. Often these BGAs comprises a so called redistribution layers (RDLs) used to connect contact pads or contact points of the chip to a substrate or package having a different contact layout or contact arrangement than the chip. However since the redistribution layer itself and the connected layers or elements comprise different materials, e.g. a supporting layer like polyimide and copper paths used for the redistribution of contact points, mechanical or thermo-mechanical stress occurs due to temperature change from assembly temperature and different thermal expansion coefficients of the different materials in the redistribution layer, the chip and optionally packages.

The repeated thermo-mechanical stress leads to repeated plastic deformation and then to breakages or failures of electrical contacts, e.g. due to breakages of the copper paths or connector lines. The copper is typically weakened by impurities of Cl and S origin from pattern plating. In order to decrease the probability of breakages of the conductor paths of the redistribution layer specific forms or shapes of the (solder) ball of the BGA and the connections of the balls to the conductor paths are used. For example, a so called teardrop design is used which is schematically shown in FIG. 5. In particular FIG. 5 schematically shows a detail of a BGA 500 having three contact points/solder balls 501, 502 and 503 two of which are connected to conductor paths 504, 505, respectively and having a teardrop design.

This teardrop design reduces the stress induced by the different temperature expansion coefficients by compensating the relative movement from the different components of the components of the RDL, the connected chip and the supporting layer. The teardrop shape of the solder balls may be sufficient to reduce the probability of breakage in BGAs having relative great balls (and thus a relative great amount of solder material for compensating) and a relative large pitch between the different balls of the grid. However, the known techniques may not be suitable anymore for a reduced ball size, e.g. less than 300 micrometer, and a reduced ball pitch, e.g. 0.5 millimeter or below, since the solder balls may not provide sufficient compensation material anymore due to a reduced volume and to increased shearing angles due to a low vertical distance between the board comprising the RDL and a used package. Solders with higher stiffness may be required but then will lead to more stress in the RDL.

Furthermore, US 2005127527 A1 discloses a general electronic component having metal-coated elevations formed of a rubber-elastic, silicone-based elastomere by a printing process. The rubber-elastic elevations are used for compensating for mechanical stress occurring and to compensate for unevenness between the electronic component and a carrier.

Thus, the probability of breakage of used solder contacts or connections in the RDL may increase in case of reduced pitch and/or in case the boards are reduced in size. In addition the problems may become more severe in case the chips shall be used in security relevant applications, e.g. in the automotive technology, having high reliability needs, while at the same time demanding relatively large sized chips due to the necessary functionality to be implemented in the chip or package.

### SUMMARY

In general, there may be a need to provide a redistribution layer and a method of forming a redistribution layer which withstands a high number of thermocycles and/or having a low probability of breakages.

According to an exemplary aspect a redistribution layer for a chip is provided, wherein the redistribution layer comprises at least one electrical conductor path connecting two connection points with each other, wherein the at least one electrical conductor path is arranged on a planar supporting layer and wherein the electrical conductor path comprises copper and at least one other further electrical conductive material in an amount of more than 0.04 mass percent.

According to an exemplary aspect a redistribution layer for a chip is provided, wherein the redistribution layer comprises at least one electrical conductor path connecting two connection points with each other, wherein the at least one electrical conductor path is arranged on a planar supporting layer and wherein the conductor path comprises a highly conductive base material and a tensile strength enhancement compound.

According to an exemplary aspect a method of forming a redistribution layer for a chip is provided, wherein the method comprises providing a planar supporting layer, forming at least one electrical conductor path on the planar supporting layer, wherein the conductor path comprises a highly conductive base material and a tensile strength enhancement compound.

The provision of a compound or material in addition to a highly conductive base material, e.g. copper, may enable that the conductor path exhibits an increased tensile strength when compared to a conductor path which is formed out of substantially pure copper as used in the art. Thus, it may be possible that the conductor paths may resist or withstand a greater number of thermocycles even when the package carrying the redistribution layer (RDL) has a size which is large, e.g. more than 8 mm×8 mm. In other words the additional compound may strengthen the conductor path by providing an increased flexibility, e.g. provides an elastic conductor path. Thus, the additional compound may increase the number of thermocycles for the RDL, and the respective chip for which the RDL is used, before a breakage of a conductor path occurs.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 shows a schematic plan view of a redistribution layer comprising strengthened conductor paths according to an exemplary embodiment;

FIG. 2A shows a schematic cross sectional view of a packaged chip;

FIG. 2B shows a schematic cross sectional view of a conductor path of the packaged chip of FIG. 2A;

FIG. 3 shows a schematic flow chart of a method of forming a redistribution layer; and

FIG. 4A to 4D schematically show cross sectional views of different tensile strength enhanced redistribution layers.

FIG. 5 shows a detail of a ball grid array.

### DESCRIPTION OF FURTHER EXEMPLARY EMBODIMENTS

In the following, further exemplary embodiments of the transducer arrangement and the method of manufacturing the same will be explained. It should be noted that embodiments described in the context of the redistribution layer may also be combined with embodiments of the method of forming the redistribution layer and vice versa.

According to an exemplary aspect a packaged chip is provided, wherein the packaged chip comprises a chip bonded to a redistribution layer according to an exemplary aspect and a ball grid array attached to the redistribution layer.

In particular, the amount of the at least one other electrical conductive material may be more than 0.05 mass percent, preferably more than 0.1% mass percent. The contact points may be formed by contact pads and/or vias.

In particular, the tensile strength enhancement compound may be an electrical conductive material, e.g. an alloy or mixture of an electrical conductive material and a further compound either conductive or non-conductive. In particular, the tensile strength enhancement compound may be formed or may be improved in a cold working or strain hardening process, e.g. when the conductor path including the tensile strength enhancement compound is exposed to stress or strain a strain hardening process may be induced, e.g. during an actual usage of an device comprising the redistribution layer.

The term “compound” may particularly denote an admixing or additive which is willingly incorporated and may have to be distinguished from an impureness or impurity which is typically present in every material. For example, the tensile strength enhancement compound may be added willingly in a sufficient amount in order to provide a tensile strength of the electrical conductor path which is above a given threshold.

The term “electrical conductive” may particularly denote any material having an electrical resistivity which is lower than a given threshold, e.g. lower than 2*10⁶ Ω*m (ohm*meter) at 20° C. Thus, according to such definition of the term “electrical conductive” some elements or compounds typically denoted as non-conductive, e.g. boron, may be considered to be “electrical conductive”. On contrast elements, having a lower electrical conductivity, like sulphur and chlorine, may not considered to be “electrical conductive” in this sense.

The term “conductor path” may particularly denote a continuous path formed by an electrical conductive material, e.g. copper. In particular, also a seed layer of copper, e.g. having a thickness of less than 1 micrometer like 0.5 micrometer, for example, may already count as a conductor path.

The term “redistribution layer” may be interpreted in a broad sense as a layer, in particular a structured metal containing layer, on a chip that makes contact points, e.g. contact pads or vias, of a chip, e.g. an integrated chip, available in another location. Thus, in this sense a layer, which is restricted in size to the size or area of the chip, e.g. a layer which is formed at the so called back end of line, may fall under this definition. However, also a layer which extends beyond the size of the chip, e.g. a layer which is formed in a packaged chip e.g. an embedded wafer level ball grid array, may fall under this definition as well.

According to an exemplary embodiment of the redistribution layer the supporting layer comprises polyimide.

Alternatively or additionally, the supporting layer may comprise polybenzoxazole (PBO). The provision of a supporting layer or an intermediate layer comprising or consisting substantially of polyimide or PBO may have the advantage that the supporting layer already exhibits some amount of flexibility or bendability improving the durability of the RDL or the RDL formed on or in the supporting layer.

According to an exemplary embodiment of the redistribution layer the package carrying the redistribution layer has a size of at least 4 mm×4 mm.

In particular, the redistribution layer may have a size of more than 8 mm×8 mm, more preferably the redistribution layer may have a size of more than 15 mm×15 mm. An upper limit for the size may be about 150 mm×150 mm or even more.

According to an exemplary embodiment of the redistribution layer the conductor paths have a tensile strength of more than 100 MPa. In particular, the tensile strength may be more than 150 MPa, 250 MPa, more particular more than 300 MPa and preferably more than 400 MPa, wherein these strengths are measured in the bulk at room temperature.

According to an exemplary embodiment of the redistribution layer the conductor path is formed by a multilayer stack having an uppermost layer.

In particular, the term “multilayer stack” may include any stack having at least two layers. A total thickness of the multilayer stack may be in the range 2 micrometer to 50 micrometer, more particular in the range of 5 micrometer to 25 micrometer, preferably in the range of 5 micrometer to 10 micrometer, e.g. about 8 micrometer.

In particular, the at least one other further electrical conductive material is formed as an additional layer on a sub conductor path of copper.

The at least one other further electrical conductive material may form an additional layer which is arranged on top of a copper layer or a sub conductor path of copper. Thus, the conductor path may be formed by a sub conductor path of copper and a sub conductor path formed by the further electrical conductive material (optionally comprising copper as well). Alternatively, the at least one other further electrical conductive material may be formed underneath the copper conductor paths or may be mixed with the copper compound and forming an alloy with the same.

The use of an additional layer for the at least one other further electrical conductive material may be an efficient way to provide a strengthening element or function for the copper compound or copper conductor paths. In particular, the provision of an extra layer may provide an efficient and flexible way to provide a strengthening element or compound, since two steps are used to form the conductor path each of which steps may be adapted to the specific needs of processing the respective materials.

According to an exemplary embodiment of the redistribution layer the at least one other further electrical conductive material is selected out of the group consisting of: tin, silver, iron, nickel, aluminium, carbon, silicon, phosphorus, titanium, vanadium, boron and any combination thereof.

In particular, all materials which are suitable for an elastic or flexible conductor path or line may be used as materials for the electrical conductive material. The at least one further electrical conductive material may be arranged in an additional layer over the copper conductor paths. Useful layer comprise In, Al, Zn, Ni. In particular, indium and tin may be a suitable material for strengthening the conductor path since already a small amount of tin within copper may increase the tensile strength of the conductor path to a sufficient amount.

According to an exemplary embodiment of the redistribution layer the at least one other further electrical conductive material forms an alloy with the copper.

In particular, in case that the alloy has a sufficient electrical conductivity it may not necessary to form conductor paths of pure or substantially pure copper. Thus, when using an alloy or mixture of copper and the further electrical conductive material for forming the conductor path it may be possible that only a single forming step for forming the conductor path is necessary instead of two or multiple sub-steps forming a highly conductive sub conductor path (comprising the copper, for example) and an additional sub conductor path (comprising the further electrical conductive material).

According to an exemplary embodiment of the redistribution layer the multilayer stack is an annealed multilayer stack.

The annealing may improve the durability and/or tensile strength of the at least one conductive path. For example, only one annealing step is performed after forming the uppermost layer of the multilayer conductor path.

According to an exemplary embodiment of the redistribution layer the uppermost layer comprises an electrical conductive material with an electrical resistivity below a given threshold.

In particular, the given threshold may be in the range of the electrical resistivity of copper. For example, the given threshold may be 3*10⁻⁸ Ω*m, in particular 2.65*10⁻⁸ Ω*m, at 20° C. For example, the uppermost layer may comprise or may (essentially) consist of copper and/or silver. The provision of an uppermost or top layer having a high electrical conductivity may allow for the provision of a redistribution layer which is suitable for high frequency applications, e.g. radio frequency, since despite the skin effect a sufficient conductivity may be ensured when using a highly conductive material for the uppermost layer.

According to an exemplary embodiment of the redistribution layer the amount of the tensile strength enhancement compound is chosen so that a tensile strength of the electrical conductor path of more than 100 MPa is achieved.

In particular, the tensile strength may be more than 200 MPa, more particular more than 250 MPa and preferably more than 300 MPa or 400 MPa, wherein the tensile strengths are measured in the bulk at room temperature.

In particular, the tensile strength enhancement compound may have a percentage of more than 0.04 mass percent.

According to an exemplary embodiment the redistribution layer is connected to a ball grid array. In particular, the ball grid array may be a wafer level ball grid array (WLB) or an embedded wafer level ball grid array (eWLB).

According to an exemplary embodiment of the redistribution layer the further electrical conductive material has a grain size of less than 2 micrometer.

In particular, the grain size may be 1 micrometer or below, e.g. in the range between 10 nanometer and 1 micrometer. The provision of a specific grain size in particular a small grain size may enable that a growing of grains of the base material of the conductor path, e.g. copper, may be avoided or at least reduced such leading to the fact that the resistance to breakage is not reduced over time, e.g. during a number of heat cycles.

According to an exemplary embodiment of the redistribution layer the tensile strength enhancement compound is selected out of the group consisting of: tin, silver, iron, nickel, aluminium, carbon, silicon, phosphorus, titanium, vanadium, boron and any combination thereof.

In particular, the tensile strength enhancement compound may be an electrical conductive material, e.g. an alloy of an electrical conductive material and a further compound either conductive or non-conductive. In particular, the highly conductive material may be copper, aluminium or silver, for example. It should be mentioned that the boron may function as a kind of adhesive or chemical binding agent binding small amounts of impurities, e.g. sulphur and/or chlorine, typically present in base materials, e.g. plating copper. Thus, in case boron is used as the tensile strength enhancement compound the electrical conductor path may comprise the base material, e.g. copper (including a small amount of impurities), and only a small amount of boron for compensating for the weakening effects of the impurities. The total amount of materials other than the base material may thus be rather low, e.g. it may be below 0.04 mass percent or even below 0.03 mass percent of the material of the electrical conductor path.

According to an exemplary embodiment the method of forming a redistribution layer for a chip further comprises forming a first sub conductor path of copper, and forming a second sub conductor path on top of the first sub conductor path which second sub conductor path comprises the strength enhancement compound.

According to an exemplary embodiment of the method of forming a redistribution layer the forming of the at least one electrical conductor path is performed by pattern plating.

In particular, a first sub-step of forming and/or the second sub-step of forming may be performed by plating. Platting may be a simple and efficient method for forming a patterned layer, i.e. conductor paths.

According to an exemplary embodiment of the method of forming a redistribution layer the at least one electrical conductor path is performed by printing, in particular by printing in a pattern.

The annealing step may increase the durability and/or flexibility of the conductor path.

According to an exemplary embodiment of the method of forming a redistribution layer for a chip the forming of the at least one electrical conductor path comprises a strain hardening step after plating the conductor path.

According to an exemplary embodiment the method of forming a redistribution layer for a chip further comprise fixing a chip to the redistribution layer.

In particular, the chip may be bonded, soldered, plated or attached in any other suitable way to the redistribution layer.

Summarizing a gist of an exemplary embodiment may be seen in providing a redistribution layer for a chip, in particular for a packaged chip, for a wafer level ball grid array or for an embedded wafer level ball grid array, having an improved strength due to the addition of an additive or an additional strengthening compound. In particular, an additional compound may be used which modifies a stiff copper contact path or conductor path leading to a conductor path exhibiting a slightly elastic or flexible characteristic.

The strengthening compound may be arranged as an additional layer or may be mixed into a base compound (preferably highly conductive, like copper or wolfram) of the conductor path. The conductor paths may connect two or more contact points, e.g. contact points and/or contact pads, with each other. Due to the strengthening compound the probability of a breakage of the conductor paths may be reduced. In particular, the number of thermocycles before a stress induced breakage occurs may be increased, so that high performance specifications may be fulfilled as demanded in specific technologies, e.g. in the automotive technology.

### DETAILED DESCRIPTION OF THE FIGURES

The above and other needs, features and advantages of the present invention will become apparent from the following description and the appended claims, taken in conjunction with the accompanying drawings, in which like parts or elements are denoted by like reference numbers.

The illustration in the drawing is schematically and not necessarily to scale.

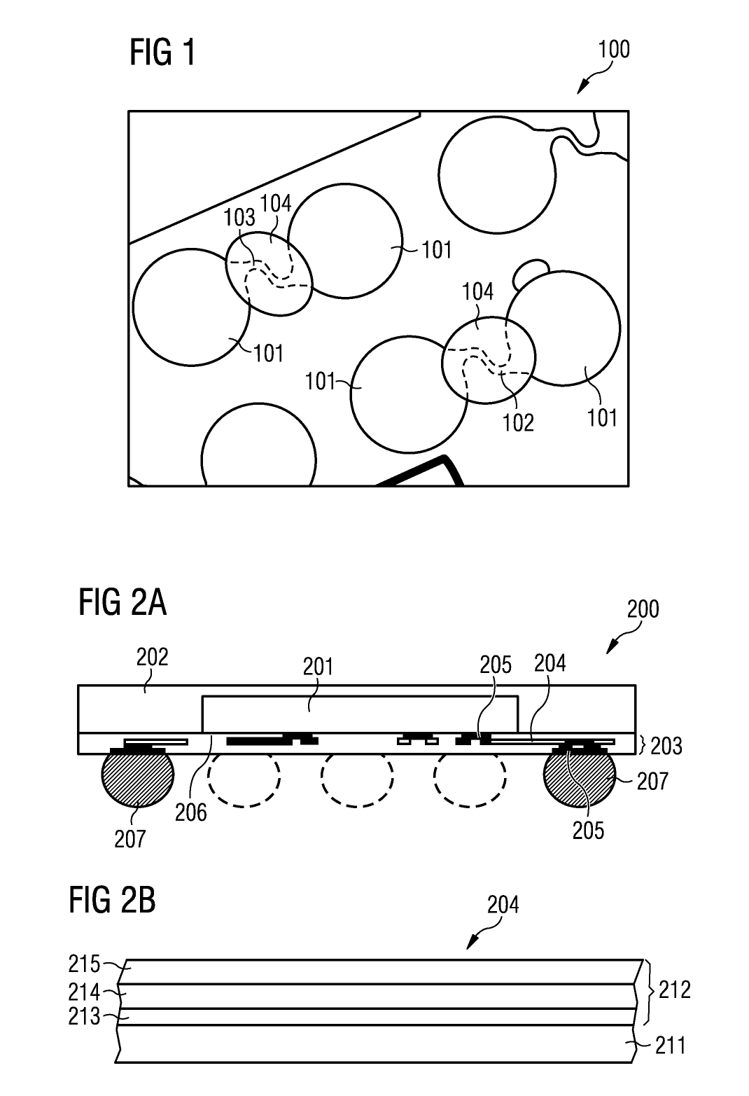

FIG. 1 shows a schematic plan view of a redistribution layer (RDL) 100 comprising strengthened conductor paths according to an exemplary embodiment. In particular FIG. 1 shows a plurality of contact points or pads 101 which are connected by conductor paths 102 and 103 on which an additional layer 104 of a tensile strength enhancement compound is formed. The tensile strength enhancement compound may be a nickel-phosphorus compound. Alternatively, the tensile strength enhancement compound may be a Cu—Sn compound, e.g. Cu3Sn, Cu6Sn5, CuSn4 or more general CuSnx, with x is lying in the range of 0.15 to 8; a CuAg0.1P compound; a CuSn0.15 compound; a CuFe2P compound; a CuFe1.8PSn compound; or a CuNi2Si compound. Alternatively, another compound may be used, e.g. Fe, Ni, Mg, Al, C, Si, P, Ti, Va, B, or any combinations thereof. All these compounds may have a sufficient conductivity and provide for a strengthening of the conductor paths. The tensile strength enhancement compound may be plated as an additional layer onto a sub conductor path (or seed layer) of copper in order to increase the strength of the conductor paths or may be mixed with a highly conductive base compound (e.g. copper or wolfram). In principle every compound may be used as the tensile strength enhancement compound which may also be used for forming contact springs or plug connectors. These materials may also be used within a chip connected to the RDL which may further improve the resistance with respect to breakages due to thermal stress.

After the plating, in particular in case of Sn or In, an annealing step may be performed finally after building the layer stack. In case of NiP also a galvanic process may be used to form the additional layer. Preferably, pattern plating is used but the additional layer may also be formed after a lack stripping and seed-etching. When forming the additional layer of NiP in a galvanic process the forming of the NiP layer may be formed by an electro-less galvanic process. However, it should be noted that the above described tensile strength enhancement compounds may be mixed with a highly conductive material (like copper) and the conductor paths may be formed in a single step and single layer comprising the mixture or alloy.

FIG. 2A shows a schematic cross sectional view of a chip package 200. In particular, the chip package 200 comprises a chip 201 molded into a mold compound 202 and connected, e.g. bonded to a first side of redistribution layer 203. The redistribution layer 203 comprises conductor paths 204 connecting contact points 205 with each other. The conductor paths 204 may be arranged on or in a dielectric supporting layer 206 and are strengthened by a tensile strength enhancement compound added to a base compound of the conductor paths, e.g. copper, or arranged as an additional layer on top of a sub conductor path of a high conductive material. The other side of the redistribution layer 203 is connected, e.g. soldered, to solder balls 207 of a ball grid array.

FIG. 2B shows a schematic cross sectional view of a conductor path 204 of the packaged chip of FIG. 2A. In particular, FIG. 2B shows a conductor path 204 comprising a layer 211 of a base material which is highly conductive. On top of this layer 211 of highly conductive base material a tensile strength enhancement layer 212 is formed or arranged. The tensile strength enhancement layer 212 comprises a plurality of sub layers three of which are indicated as 213, 214 and 215 in FIG. 2B. However, in reality a higher or lower number of sub layers may be used. Some or all of the sub layers of the tensile strength enhancement layer 212 comprise a material which is suitable to enhance the tensile strength of the total conductor path 204. For example, the sub layers may comprise or may consist of a Cu—Sn compound, e.g. Cu3Sn, Cu6Sn5, CuSn4; a CuAg0.1P compound; a CuSn0.15 compound; a CuFe2P compound; a CuFe1.8PSn compound; a CuNi2Si compound; or a NiP compound. It should be noted that the single sub layers may comprise or may consist of different materials or the same material(s). Preferably, the upper most layer or sub layer of the conductor path 204 comprises or consists again of a highly conductive material like copper.

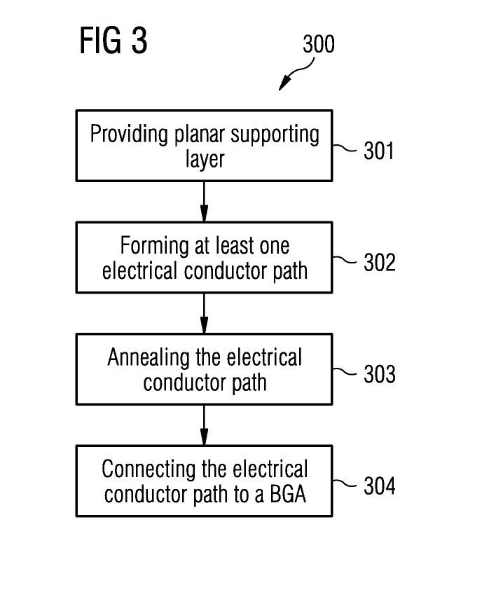

FIG. 3 shows a schematic flow chart of a method of forming a redistribution layer 300. In particular, in a first step a planar supporting layer or structure is provided 301, which comprises polyimide for example. In or on the supporting layer at least one electrical conductor path is formed 302, e.g. by plating or a galvanic process. The electrical conductor path may be formed by a single layer having sufficient electrical conductivity or may be formed by two sub layers. In case to sub layers or two sub conductor paths are formed on top of each other, the first sub conductor path may be formed by a highly conductive material, e.g. copper or wolfram, and the second sub conductor path may be formed by a tensile strength enhancement compound. In case as the tensile strength enhancement compound a layer comprising nickel (optionally further comprising phosphorous) is used, the content of the nickel is preferably exactly controlled in a galvanic process.

With these steps the redistribution layer is in principle formed. However, after the forming of the at least one conductor path additional optional steps may be performed, e.g. an annealing step 303, which may be performed in case tin or indium is used in a layer over a copper layer, and/or a step connecting the RDL to a BGA 304 and/or a step connecting the RDL to a chip. In addition or alternatively to the optional annealing step a cold working process or strain hardening process may be performed on the conductor path during the manufacturing of the RDL or even during the use of the RDL. In such a cold working process the strength of the conductor path will be increased during the first stress or strain cycles of the RDL, e.g. in the case that nickel or boron are used as the tensile strength enhancement compound. During such a process a mixed crystal may be formed having an improved strength and thus may enable an improved lifetime of an IC-RDL connection. In particular, boron may function as a kind of adhesive compensating for the small impurities within plated copper (typically sulphur and chlorine) which typically reduces the strength of the copper.

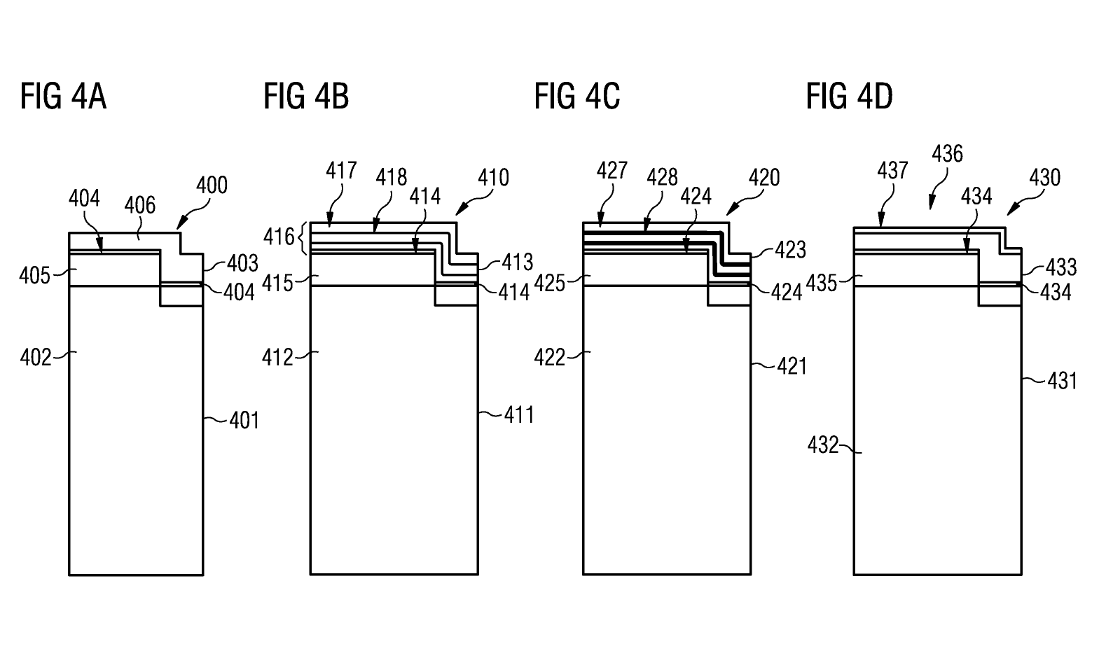

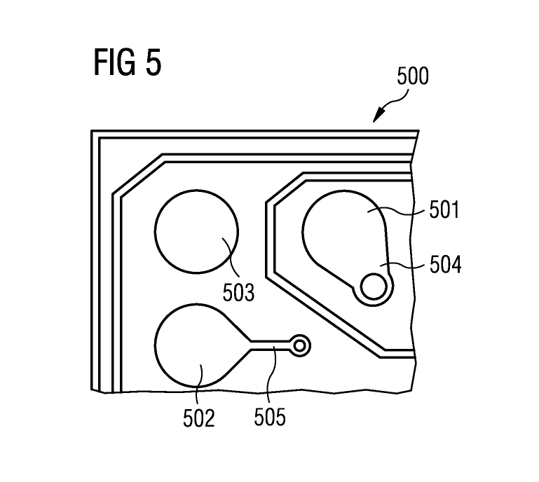

FIG. 4A to 4D schematically show cross sectional views of different tensile strength enhanced redistribution layers. It should be stressed that the cross sectional views given in the FIGS. 4A to 4D are schematic, e.g. under real conditions the corners, edges may be rather rounded than straight and sharp as shown in the figures.

In particular, FIG. 4A shows an example of an RDL 400 arranged on an IC 401 which is molded in a molding compound 402. The RDL 400 comprises a via 403 contacting the IC 401. The via 402 is formed on a copper seed layer 404 which is also formed on a polyimide layer 405 formed on the mold 402 functioning as a planar supporting layer for the RDL 400. Furthermore, the RDL 400 comprises a single conductor path layer 406 comprising a copper tin compound CuSnx. It should be mentioned that it should be ensured that the CuSnx compound has a sufficient electrical conductivity. In that case a single compound or alloy is used so that the RDL can be manufactured with low costs. Aside from CuSnx, wherein x is in the range of 0.1 to 8, e.g. 0.15, copper iron phosphorous compounds like CuFe0.1P or CuFe2P, copper zinc compounds CuSnx, wherein x is in the range of 20 to 37, e.g. 25, or copper chromo compounds CuCrx, wherein x is in the range of 0.3 to 1.2 may be used. All these compounds may be plateable compounds and may thus easily be used when forming the conductor path in a plating process. Alternatively small amounts of boron and/or nickel (e.g. nickel boron NiBx, wherein x is in the range of 1 to 30, e.g. 2), nickel phosphorous (e.g. NiPx, wherein x is in the range of 3 to 30, e.g. 7), carbon, silicon, silver phosphorous (AgP), iron phosphorous (FeP), titanium, vanadium or chromo may be used.

In particular, FIG. 4B shows an example of an RDL 410 arranged on an IC 411 which is molded in a molding compound 412. The RDL 410 comprises a via 413 contacting the IC 411. The via 413 is formed on a copper seed layer 414 which is also formed on a polyimide layer 415 formed on the mold 412 functioning as a planar supporting layer for the RDL 410. In contrast to the example given in FIG. 4A the RDL 410 does not comprise a single conductor path layer but a multilayer structure 416. In particular, multilayer structure or multilayer stack 416 comprises several layers of copper 417 and tin 418 which are arranged in an alternating manner on top of each other, so that an interleaving multilayer stack is formed. It should be noted that an uppermost layer of the multilayer stack 416 is a layer having low electrical resistance, e.g. copper. Preferably, the tin layer is thinner, e.g. less than 1 micrometer, than the copper layer. The copper layer may be thicker, e.g. by a factor of 3, than the tin layer. By heating the multilayer stack 416 after the last sub layer is deposited a heating step may be performed so that a copper-tin alloy is formed, e.g. Cu5Sn6 and/or Cu3Sn. In comparison to the embodiment shown in FIG. 4A, the one shown in FIG. 4B has higher electrical conductivity and a higher strength but may be more costly in manufacturing. Alternatively or additionally to tin, indium may be used as well.

In particular, FIG. 4C shows an example of an RDL 420 arranged on an IC 421 which is molded in a molding compound 422. The RDL 420 comprises a via 423 contacting the IC 411. The via 413 is formed on a copper seed layer 424 which is also formed on a polyimide layer 425 formed on the mold 422 functioning as a planar supporting layer for the RDL 420. The example is similar than the one given in FIG. 4C but nickel 428 is used instead of the tin of the example of FIG. 4B for the layers interleaving the copper layers 427. Preferably, the nickel layers comprise nickel having a grain size of less than 1 micrometer. In comparison to the embodiment shown in FIG. 4A, the one shown in FIG. 4C has higher electrical conductivity and a higher strength but may be more costly in manufacturing. Alternatively or additionally to the nickel palladium, vanadium or titanium may be used. Alternatively, tantalum and/or a multilayer structure of titanium-wolfram-titanium may be used.

In particular, FIG. 4D shows an example of an RDL 430 arranged on an IC 431 which is molded in a molding compound 432. The RDL 430 comprises a via 433 contacting the IC 431. The via 432 is formed on a copper seed layer 434 which is also formed on a polyimide layer 435 formed on the mold 432 functioning as a planar supporting layer for the RDL 430. Furthermore, the RDL 430 comprises a conductor path layer 436 comprising a copper nickel silicon compound CuNi2Si, as example for a very stable RDL in the expense of conductivity. In order to further reduce the resistance of the conductor path and in order to ensure an improved radio frequency performance a copper top layer 437 or alternatively a silver top layer is arranged on top of the CuNi2Si layer. It should be mentioned that in principle the same compounds as described above in the context of FIG. 4A may be used.

It should be noted that in case that the strengthening compound itself has a sufficiently high conductivity the base conductor path of copper may be omitted, e.g. the conductor paths comprising a copper base material and the strengthening compound may be formed only when forming the RDL. That is in this case a base conductor RDL layer may be omitted and the conductor may be formed by a semi-additive galvanic process and/or etching process from a single layer comprising copper as a base material and the tensile strength enhancement compound. Further the outermost layer of thickness due to skin depths shall be pure copper or an element or alloy close to its conductivity for better RF signal transmission.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A redistribution layer for a chip, the redistribution layer comprising:
at least one electrical conductor path connecting two connection points with each other, wherein the at least one electrical conductor path is arranged on a planar supporting layer and wherein the electrical conductor path comprises copper and at least one other further electrical conductive material in an amount of more than 0.04 mass percent.

2. The redistribution layer according to claim 1, wherein the supporting layer comprises polyimide.

3. The redistribution layer according to claim 1, wherein a package of the redistribution layer has a size of at least 4 mm×4 mm.

4. The redistribution layer of claim 1, wherein the at least one electrical conductor path have a tensile strength of more than 100 MPa.

5. The redistribution layer according to claim 1, wherein the conductor path is formed by a multilayer stack comprising an uppermost layer.

6. The redistribution layer according to claim 5, wherein the multilayer stack is an annealed multilayer stack.

7. The redistribution layer according to claim 5, wherein the uppermost layer comprises an electrical conductive material with an electrical resistivity below a given threshold.

8. The redistribution layer according to claim 1, wherein the at least one other further electrical conductive material is selected out of the group consisting of:
tin, silver, iron, nickel, aluminium, carbon, silicon, phosphorus, titanium, vanadium, boron and any combination thereof.

9. The redistribution layer according to claim 1, wherein the redistribution layer is connected to a ball grid array.

10. The redistribution layer according to claim 1, wherein the further electrical conductive material has a grain size of less than 2 micrometer.

11. A redistribution layer for a chip, the redistribution layer comprising:
at least one electrical conductor path connecting two connection points with each other, wherein the at least one electrical conductor path is arranged on a planar supporting layer and wherein the conductor path comprises a highly conductive base material and a tensile strength enhancement compound.

12. The redistribution layer according to claim 11, wherein the amount of the tensile strength enhancement compound is chosen so that the electrical conductor path has a tensile strength of more than 100 MPa.

13. The redistribution layer according to claim 11, wherein the tensile strength enhancement compound is selected out of the group consisting of:
tin, silver, iron, nickel, aluminium, carbon, silicon, phosphorus, titanium, vanadium, boron and any combination thereof.

14. The redistribution layer according to claim 11, wherein the tensile strength enhancement compound forms an alloy with the copper of the at least one electrical conductor path.

15. Method of forming a redistribution layer for a chip, the method comprising:
providing a planar supporting layer; and
forming at least one electrical conductor path on the planar supporting layer, wherein the conductor path comprises a highly conductive base material and a tensile strength enhancement compound.

16. The method according to claim 15, wherein the forming of at least one electrical conductor path comprises:
forming a first sub conductor path of copper; and
forming a second sub conductor path on top of the first sub conductor path which second sub conductor path comprises the strength enhancement compound.

17. The method according to claim 15, wherein the forming of the at least one electrical conductor path is performed by plating.

18. The method according to claim 15, wherein the forming of the at least one electrical conductor path is performed by printing.

19. The method according to claim 15, wherein the forming of the at least one electrical conductor path comprises an annealing step after completing the conductor path.

20. The method according to claim 15, further comprising fixing a chip to the redistribution layer.
